(19) United States
(12) Patent Application Publication
(10) Pub. No.: US 2026/0088206 A1
(43) Pub. Date: Mar. 26, 2026

(54) HIGH-Q WIDE BAND SWITCHABLE TRANSFORMER

(71) Applicant: QUALCOMM Incorporated, San Diego, CA (US)

(72) Inventors: Ning YUAN, San Diego, CA (US); Yung-Chung LO, San Diego, CA (US); Raviteja GAJULA, San Diego, CA (US); Jagdish PANDEY, San Diego, CA (US); Maulin BHAGAT, Bangalore (IN); Arup RAY, Kalyani (IN); Jeongil Jay KIM, San Diego, CA (US)

(21) Appl. No.: 18/894,388

(22) Filed: Sep. 24, 2024

(51) Int. Cl. H01F 21/12; H03D 7/12; H03F 3/24; H04B 1/00; H04B 1/04

(52) U.S. Cl. CPC H01F 21/12; H03D 7/12; H03F 3/245; H04B 1/006; H04B 1/04; H03F 2200/451; H04B 2001/0491

(57) ABSTRACT

A system includes a mixer, an amplifier, and a switchable transformer. The switchable transformer includes a primary inductor coupled between a first output and a second output of the mixer, a first switch, a second switch, and a secondary inductor coupled between a first input and a second input of the amplifier, wherein the secondary inductor is magnetically coupled with the primary inductor. The secondary inductor includes a first inductor coupled between the first input of the amplifier and a first terminal of the first switch, a second inductor coupled between a second terminal of the first switch and the second input of the amplifier, a third inductor coupled between the first terminal of the first switch and a first terminal of the second switch, and a fourth inductor coupled between the second terminal of the first switch and a second terminal of the second switch.

### BACKGROUND

### Field

Aspects of the present disclosure relate generally to wireless communications, and, more particularly, to switchable transformers.

### Background

A wireless device includes a transmit circuit for transmitting radio frequency (RF) signals via one or more antennas. The transmit circuit may include a mixer for frequency upconverting a baseband signal or an intermediate frequency (IF) into a radio frequency (RF) signal and a power amplifier for amplifying the RF signal before transmission. The transmit circuit may also include a driver amplifier coupled between the mixer and the power amplifier for driving the power amplifier with the RF signal from the mixer.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system. The system includes a mixer, an amplifier, and a switchable transformer. The switchable transformer includes a primary inductor coupled between a first output and a second output of the mixer, a first switch, a second switch, and a secondary inductor coupled between a first input and a second input of the amplifier, wherein the secondary inductor is magnetically coupled with the primary inductor. The secondary inductor includes a first inductor coupled between the first input of the amplifier and a first terminal of the first switch, a second inductor coupled between a second terminal of the first switch and the second input of the amplifier, a third inductor coupled between the first terminal of the first switch and a first terminal of the second switch, and a fourth inductor coupled between the second terminal of the first switch and a second terminal of the second switch.

A second aspect relates to a system. The system includes a mixer, a driver amplifier, a power amplifier coupled to an output of the driver amplifier, and a switchable transformer. The switchable transformer includes a primary inductor coupled between a first output and a second output of the mixer, a first switch, a second switch, and a secondary inductor coupled between a first input and a second input of the driver amplifier, wherein the secondary inductor is magnetically coupled with the primary inductor. The secondary inductor includes a first inductor coupled between the first input of the driver amplifier and a first terminal of the first switch, a second inductor coupled between a second terminal of the first switch and the second input of the driver amplifier, a third inductor coupled between the first terminal of the first switch and a first terminal of the second switch, and a fourth inductor coupled between the second terminal of the first switch and a second terminal of the second switch.

A third aspect relates to a method for operating a wireless device. The wireless device includes a switchable transformer coupled between a mixer and an amplifier, the switchable transformer including a primary inductor and a secondary inductor magnetically coupled with the primary inductor, the secondary inducting including a first inductor, a second inductor, a third inductor, and a fourth inductor. The method includes, in a first mode, coupling the first inductor, the second inductor, the third inductor, and the fourth inductor in series between a first input and a second input of the amplifier. The method also includes, in a second mode, coupling the first inductor and the second inductor in series between the first input and the second input of the amplifier, wherein the first inductor and the second inductor bypass the third inductor and the fourth inductor.

### BRIEF DESCRIPTION OF THE DRAWINGS

FIG. 1 shows an example of a transmit circuit including a mixer, a driver amplifier, and a transformer between the mixer and the driver amplifier according to certain aspects of the present disclosure.

FIG. 2A shows an example of a switchable transformer in a first mode according to certain aspects of the present disclosure.

FIG. 2B shows an example of the switchable transformer of FIG. 2A in a second mode according to certain aspects of the present disclosure.

FIG. 3A shows another example of a switchable transformer in a first mode according to certain aspects of the present disclosure.

FIG. 3B shows an example of the switchable transformer of FIG. 3A in a second mode according to certain aspects of the present disclosure.

FIG. 4A shows yet another example of a switchable transformer in a first mode according to certain aspects of the present disclosure.

FIG. 4B shows an example of the switchable transformer of FIG. 4A in a second mode according to certain aspects of the present disclosure.

FIG. 5A shows an exemplary layout of a switchable transformer including a primary inductor and a secondary inductor according to certain aspects of the present disclosure.

FIG. 5B shows the layout of FIG. 5A without the secondary inductor according to certain aspects of the present disclosure.

FIG. 5C shows the layout of FIG. 5A without the primary inductor according to certain aspects of the present disclosure.

FIG. 6A shows another exemplary layout of a switchable transformer including a primary inductor and a secondary inductor according to certain aspects of the present disclosure.

FIG. 6B shows the layout of FIG. 6A without the secondary inductor according to certain aspects of the present disclosure.

FIG. 6C shows the layout of FIG. 6A without the primary inductor according to certain aspects of the present disclosure.

FIG. 7 is a diagram of an environment including an electronic device that includes a transceiver according to certain aspects of the present disclosure.

FIG. 8 is a flowchart illustrating a method for operating a wireless device according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

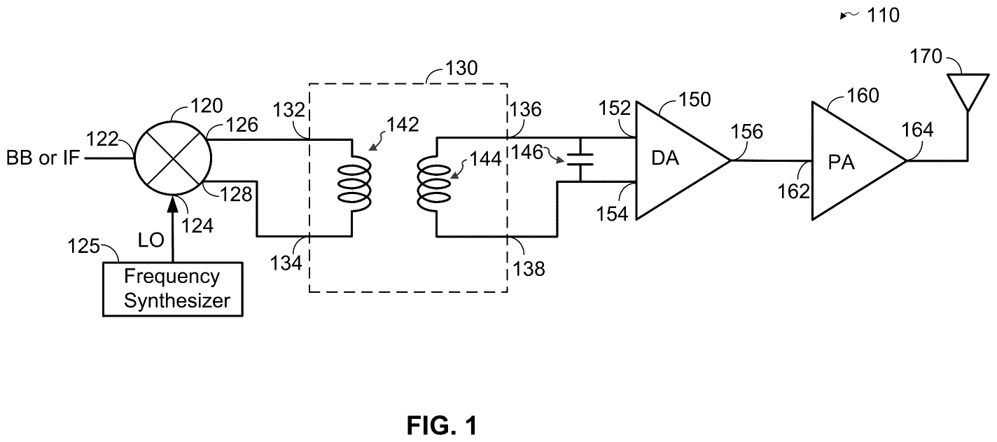

FIG. 1 shows an example of a transmit circuit 110 including a mixer 120, a transformer 130, a driver amplifier 150, and a power amplifier 160. The transmit circuit 110 may also be referred to as a transmit path, a transmit chain, or another term. The transmit circuit 110 may be included in a wireless device (e.g., a mobile device or a base station) for transmitting RF signals via one or more antennas.

The mixer 120 has a first input 122, a second input 124, and a differential output including a first output 126 and a second output 128. The mixer 120 is configured to receive a baseband signal (labeled “BB” in FIG. 1) or an intermediate frequency (IF) signal at the first input 122 and a local oscillator signal (LO) at the second input 124. The LO signal is generated by a frequency synthesizer 125 (e.g., a phase-locked loop (PLL)) coupled to the second input 124 of the mixer 120. For the example in which the first input 122 of the mixer 120 receives the baseband signal, the first input 122 may be coupled to a baseband processor, a baseband filter, and the like. For the example in which the first input 122 of the mixer 120 receives the IF signal, the input 122 may be coupled an IF circuit configured to frequency upconvert a baseband signal into the IF signal. The IF signal has a frequency between baseband and the frequency of the RF signal.

The transformer 130 includes a primary inductor 142 and a secondary inductor 144 inductively (i.e., magnetically) coupled with the primary inductor 142. The primary inductor 142 is coupled between a first terminal 132 and a second terminal 134 of the transformer 130, and the secondary inductor 144 is coupled between a third terminal 136 and a fourth terminal 138 of the transformer 130. The first terminal 132 is coupled to the first output 126 of the mixer 120, and the second terminal 134 is coupled to the second output 128 of the mixer 120. Thus, in this example, the primary inductor 142 is coupled between the first output 126 and the second output 128 of the mixer 120.

In this example, the driver amplifier 150 has a differential input including a first input 152 and a second input 154. The driver amplifier 150 also has an output 156, which may be a single-ended output or a differential output. In the example in FIG. 1, the first input 152 is coupled to the third terminal 136 of the transformer 130, and the second input 154 is coupled to the fourth terminal 138 of the transformer 130. Thus, in this example, the secondary inductor 144 is coupled between the first input 152 and the second input 154 of the driver amplifier 150.

The power amplifier 160 has an input 162 and an output 164, in which the input 162 is coupled to the output 156 of the driver amplifier 150. The output 164 of the power amplifier 160 may be coupled to an antenna 170. For example, the output 164 may be coupled to the antenna 170 through a transformer, a diplexer, a duplexer, a transmission line, or any combination thereof. The input 162 may be a single-ended input or a differential input, and the output 164 may be a single-ended output or a differential output. The driver amplifier 150 and the power amplifier 160 may be integrated on separate chips or integrated on the same chip.

During operation, the mixer 120 receives the baseband signal or the IF signal at the first input 122 and receives the LO signal from the frequency synthesizer 125 at the second input 124. The mixer 120 mixes the baseband signal or the IF signal with the LO signal to frequency upconvert the baseband signal or the IF signal into an RF signal. In the example in FIG. 1, the mixer 120 outputs the RF signal as a differential RF signal at the first and second outputs 126 and 128 of the mixer 120.

The transformer 130 receives the RF signal from the outputs 126 and 128 of the mixer 120 and magnetically couples the RF signal to the inputs 152 and 154 of the driver amplifier 150 through the magnetic coupling between the primary inductor 142 and the secondary inductor 144. The driver amplifier 150 drives the input 162 of the power amplifier 160 with the RF signal. The power amplifier 160 then amplifies the RF signal, and outputs the resulting amplified RF signal at the output 164 (e.g., for transmission via the antenna 170).

The transformer 130 may be used, for example, to provide a voltage gain from the mixer 120 to the driver amplifier 150 by stepping up the voltage of the RF signal from the mixer 120. The voltage gain allows the output voltage swing of the mixer 120 to be lower, which improves the linearity of the mixer 120. The transformer 130 may also be used, for example, to improve third-order harmonic rejection.

The transformer 130 may be configured to have a resonance frequency at or close to a frequency (e.g., center frequency) of the RF signal from the mixer 120 to provide for efficient transfer of energy from the mixer 120 to the driver amplifier 150. This also provides resistive impedance at the frequency of the RF signal, which improves bandtilt. Bandtilt or channel tilt is the tilt in the passband frequency response of a transmitter where the upper sideband (in reference to the local oscillator frequency) experiences a gain different from that for the lower sideband.

In the example in FIG. 1, the transmit circuit 110 also includes a capacitor 146 for configuring the resonance frequency of the transformer 130. In this example, the resonance frequency of the transformer 310 depends on the inductances of the primary and secondary inductors 142 and 144 and the capacitance of the capacitor 146. Thus, in this example, the inductances of the primary and secondary inductors 142 and 144 and/or the capacitance of the capacitor 146 may be chosen to achieve a desired resonance frequency (e.g., a resonance frequency at or close to the frequency of the RF signal from the mixer 120). In certain aspects, the capacitor 146 may include a variable capacitor having a tunable capacitance. This allows the resonance frequency of the transformer 130 to be tuned by tuning the capacitance of the capacitor 146. In this example, the variable capacitor may be implemented with a switchable capacitor bank (also referred to as a switchable capacitor array) and/or another type of variable capacitor.

In the example in FIG. 1, the capacitor 146 is coupled between the third terminal 136 and the fourth terminal 138 of the transformer 130. However, it is to be appreciated that the present disclosure is not limited to this example. It is also to be appreciated that the transmit circuit 110 may also include one or more additional capacitors not shown in FIG. 1 in some implementations.

In certain aspects, it is desirable for the transmit circuit 110 to support the transmission of RF signals in multiple frequency bands (e.g., to support different wireless technologies). The multiple frequency bands may include a first frequency band and a second frequency band where the second frequency band may be higher than the first frequency band. For example, the first frequency band may include a 5G band (e.g., 3.3 GHz to 5 GHZ) and the second frequency band may include a new radio unlicensed (NRU) band (e.g., 5 GHz to 7.1 GHZ). In this example, the driver amplifier 150 may be configured to amplify RF signals over a combined frequency band (e.g., 3.3 GHZ to 7.1 GHz) that covers both the first frequency band and the second frequency band. The power amplifier 160 may also be configured to amply RF signals over the combined frequency band. It is to be appreciated that the first frequency band and the second frequency band are not limited to the example of the 5G band and the NRU band.

To support transmission of RF signals in the first frequency band and the second frequency band, the transformer 130 needs to cover both the first frequency band and the second frequency. One approach to achieve this is to use separate transformers for the first frequency band (e.g., the 5G band) and the second frequency band (e.g., the NRU band). In this approach, the transformer for the first frequency band has a resonance frequency within the first frequency band and the transformer for the second frequency band has a resonance frequency within the second frequency band. However, using separate transformers for the first frequency band and the second frequency band increases chip area and cost.

To address the above, aspects of the present disclosure provide a switchable transformer configured to switch between a resonance frequency within the first frequency band (e.g., 5G band) and a resonance frequency within in the second frequency band (e.g., NRU band) to support both the first frequency band and the second frequency band. Combining the functionalities of the separate transformers discussed above into the switchable transformer results in a significant reduction in chip area and cost. The above features and other features of the present disclosure are discussed further below.

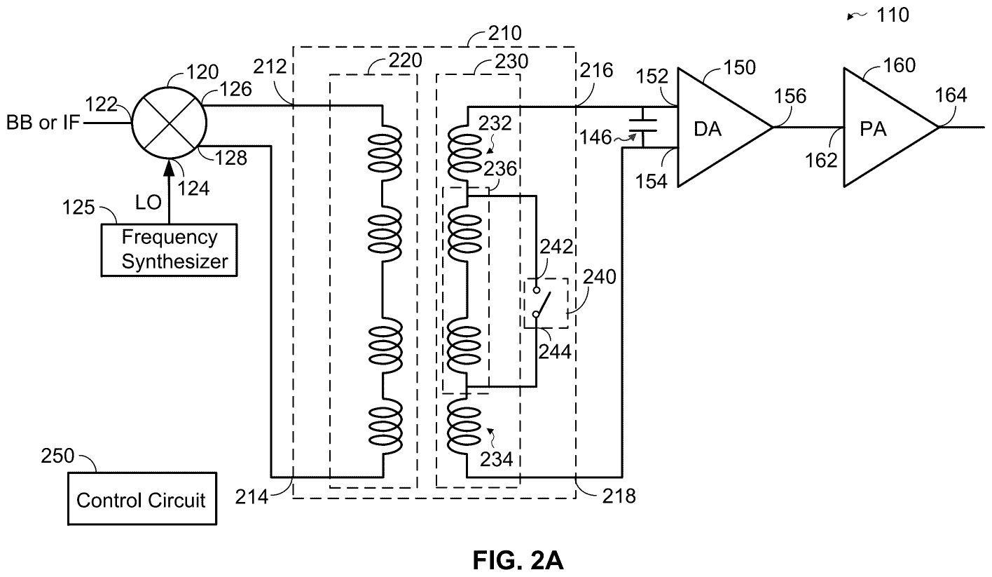

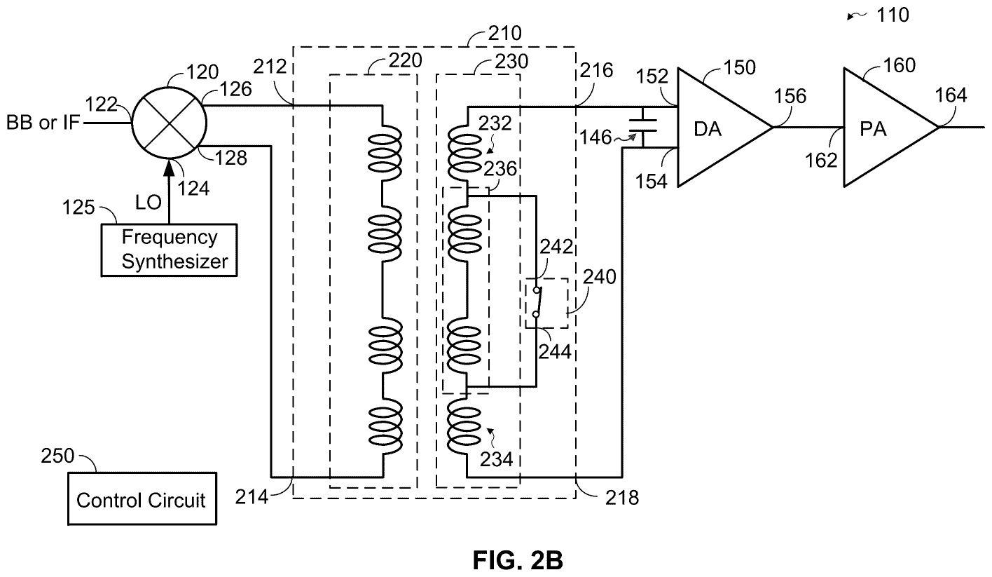

FIG. 2A shows an example of a switchable transformer 210 according to certain aspects of the present disclosure. As discussed further below, the switchable transformer 210 supports the first frequency band (e.g., the 5G band) and the second frequency band (e.g., the NRU), and, therefore, significantly reduces chip area compared with using separate transformers for the first frequency band and the second frequency band. In the example in FIG. 2A, the switchable transformer 210 is included in the transmit circuit 110, in which the switchable transformer 210 replaces the transformer 130 shown in FIG. 1. As used herein, a “switchable transformer” is a transformer including one or more switches.

The switchable transformer 210 includes a primary inductor 220, a secondary inductor 230 inductively (i.e., magnetically) coupled with the primary inductor 220, and a switch 240. It is to be appreciated that each of the inductors 220 and 230 may include two or more inductors coupled in series and/or parallel.

In the example in FIG. 2A, the primary inductor 220 is coupled between a first terminal 212 and a second terminal 214 of the switchable transformer 210, and the secondary inductor 230 is coupled between a third terminal 216 and a fourth terminal 218 of the switchable transformer 210. The first terminal 212 is coupled to the first output 126 of the mixer 120, and the second terminal 214 is coupled to the second output 128 of the mixer 120. Thus, in this example, the primary inductor 220 is coupled between the first output 126 and the second output 128 of the mixer 120. The third terminal 216 is coupled to the first input 152 of the driver amplifier 150, and the fourth terminal 218 is coupled to the second input 154 of the driver amplifier 150. Thus, in this example, the secondary inductor 230 is coupled between the first input 152 and the second input 154 of the driver amplifier 150.

In the example in FIG. 2A, the secondary inductor 230 includes a first inductor 232, a second inductor 234, and a third inductor 236. In this example, the third inductor 236 is coupled between a first terminal 242 of the switch 240 and a second terminal 244 of the switch 240. Thus, in this example, the third inductor 236 is coupled in parallel with the switch 240. The first inductor 232 is coupled between the first terminal 242 of the switch 240 and the third terminal 216 of the switchable transformer 210, and the second inductor 234 is coupled between the second terminal 244 of the switch 240 and the fourth terminal 218 of the switchable transformer 210.

In this example, the on/off state of the switch 240 is controlled by a control circuit 250. For case of illustration, the connection between the switch 240 and the control circuit 250 is not shown in FIG. 2A. The switch 240 may be implemented with one or more transistors, a transmission gate, or another type of switch. The control circuit 250 may be implemented with a processor, gated logic, a field programmable gate array (FPGA), programmable logic devices (PLDs), discrete hardware circuits, and/or any combination thereof.

In this example, the control circuit 250 switches the switchable transformer 210 between operation in the first frequency band (e.g., the 5G band) in a first mode and operation in the second frequency band (e.g., the NRU band) in a second mode by controlling the on/off state of the switch 240. More particularly, the control circuit 250 turns off the switch 240 for operation in the first frequency band in the first mode and turns on the switch 240 for operation in the second frequency band in the second mode. FIG. 2A shows an example in which the switch 240 is turned off (i.e., opened) in the first mode, and FIG. 2B shows an example in which the switch 240 is turned on (i.e., closed) in the second mode. In this example, the frequency synthesizer 125 may be configured to tune the frequency of the LO signal such that the mixer 120 converts the baseband signal or the IF signal into an RF signal in the first frequency band in the first mode and converts the baseband signal or the IF signal into an RF signal in the second frequency band in the second mode.

In this example, the secondary inductance of the switchable transformer 210 is lower in the second mode than the first mode. This is because the third inductor 236 contributes to the secondary inductance when the switch 240 is turned off in the first mode and the third inductor 236 is bypassed by the switch 240 when the switch 240 is turned on (i.e., closed) in the second mode. The primary inductance of the switchable transformer 210 can also be tuned using the switch 240 through mutual coupling. In this example, the primary inductance is also lower when the switch 240 is turned on in the second mode. Thus, in this example, the switch 240 may be used to tune both the primary inductance and the second inductance.

The lower secondary and primary inductances in the second mode cause the resonance frequency of the switchable transformer 210 to be higher in the second mode than the first mode. This allows the switchable transformer 210 to be switched between a lower resonance frequency in the first mode and a higher resonance frequency in the second mode. In this example, the inductances of the inductors 220, 232, 234, and 236 and the capacitance of the capacitor 146 may be chosen such that the resonance frequency of the switchable transformer 210 is within the first frequency band when the switch 240 is turned off in the first mode and the resonance frequency of the switchable transformer 210 is within the second frequency band (which is higher than the first frequency band) when the switch 240 is turned on in the second mode. This allows the switchable transformer 210 to support both the first frequency band (e.g., the 5G band) and the second frequency band (e.g., the NRU), and, therefore, significantly reduce chip area compared with using separate transformers for the first frequency band and the second frequency band.

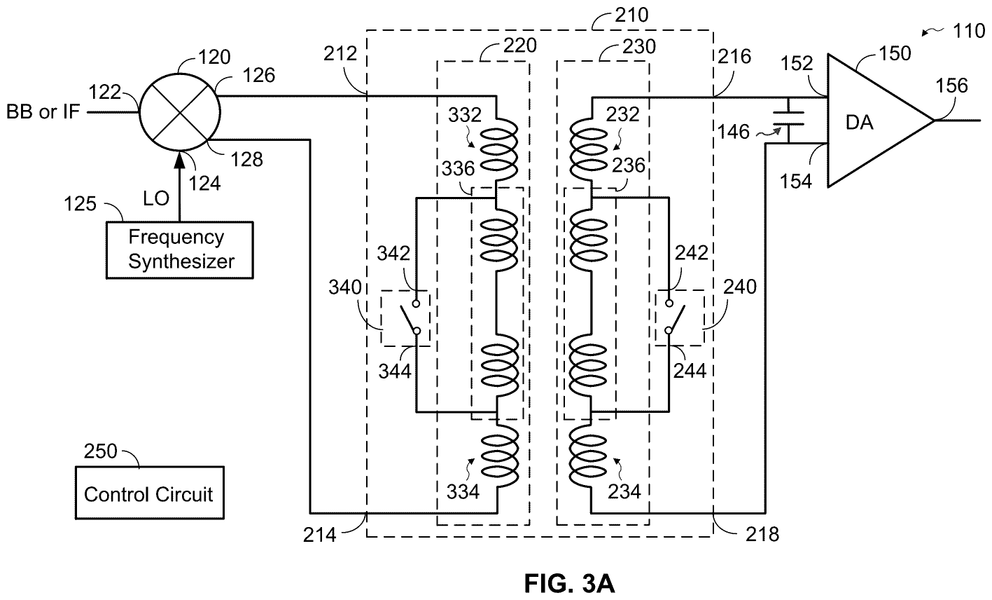

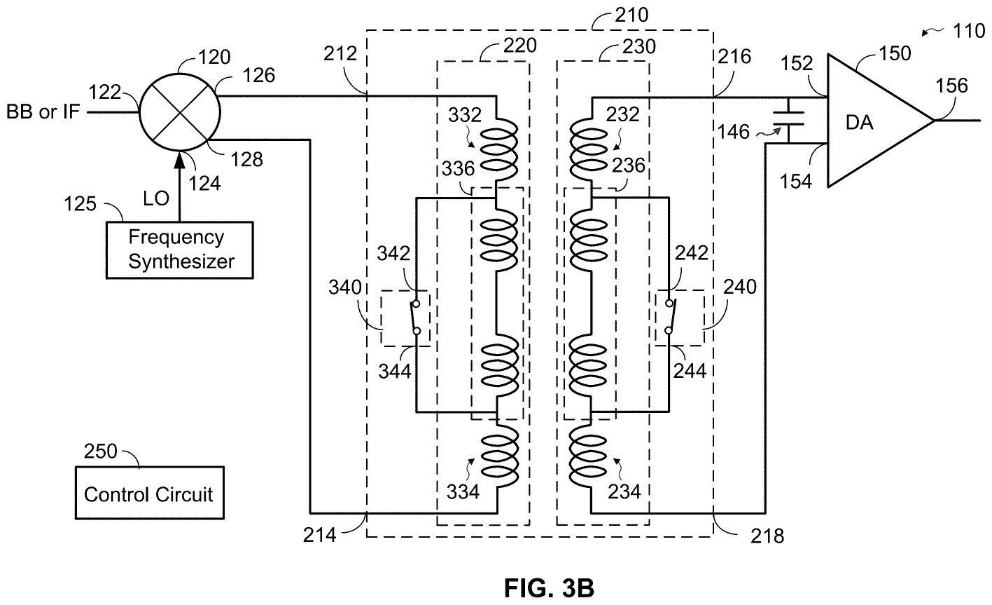

FIG. 3A shows an example in which the switchable transformer 210 further includes a second switch 340 coupled to the primary inductor 220. The second switch 340 provides an additional degree of freedom in tuning the primary and secondary inductances of the switchable transformer 210 (and hence provides greater flexibility to inductance tuning) compared with using only the switch 240. In the discussion below, the switch 240 is referred to as the first switch 240. Note that the power amplifier 160 is not shown in FIG. 3A.

In the example in FIG. 3A, the primary inductor 220 includes a first inductor 332, a second inductor 334, and a third inductor 336. In this example, the third inductor 336 is coupled between a first terminal 342 of the second switch 340 and a second terminal 344 of the second switch 340. Thus, in this example, the third inductor 336 is coupled in parallel with the second switch 340. The first inductor 332 is coupled between the first terminal 342 of the switch 340 and the first terminal 212 of the switchable transformer 210, and the second inductor 334 is coupled between the second terminal 344 of the switch 340 and the second terminal 214 of the switchable transformer 210.

In this example, the on/off state of the second switch 340 is controlled by the control circuit 250. For case of illustration, the connection between the second switch 340 and the control circuit 250 is not shown in FIG. 3A.

In this example, the control circuit 250 switches the switchable transformer 210 between operation in the first frequency band (e.g., the 5G band) in the first mode and operation in the second frequency band (e.g., the NRU band) in the second mode by controlling the on/off states of the switches 240 and 340. More particularly, the control circuit 250 turns off the switches 240 and 340 for operation in the first frequency band in the first mode and turns on the switches 240 and 340 for operation in the second frequency band in the second mode. FIG. 3A shows an example in which the switches 240 and 340 are turned off (i.e., opened) in the first mode, and FIG. 3B shows an example in which the switches 240 are turned on (i.e., closed) in the second mode.

In this example, the secondary inductance of the switchable transformer 210 is lower in the second mode than the first mode. This is because the third inductor 236 contributes to the secondary inductance when the first switch 240 is turned off in the first mode and the third inductor 236 is bypassed by the first switch 240 when the first switch 240 is turned on (i.e., closed) in the second mode. The primary inductance of the switchable transformer 210 is also lower in the second mode than the first mode. This is because the third inductor 336 contributes to the primary inductance when the second switch 340 is turned off in the first mode and the third inductor 336 is bypassed by the second switch 340 when the second switch 340 is turned on (i.e., closed) in the second mode.

The lower secondary and primary inductances in the second mode cause the resonance frequency of the switchable transformer 210 to be higher in the second mode than the first mode. This allows the switchable transformer 210 to be switched between a lower resonance frequency in the first mode and a higher resonance frequency in the second mode. In this example, the inductances of the inductors 220, 232, 234, and 236 and the capacitance of the capacitor 146 may be chosen such that the resonance frequency of the switchable transformer 210 is within the first frequency band when the switches 240 and 340 are turned off in the first mode and the resonance frequency of the switchable transformer 210 is within the second frequency band (which is higher than the first frequency band) when the switches 240 and 340 are turned on in the second mode. This allows the switchable transformer 210 to support both the first frequency band (e.g., the 5G band) and the second frequency band (e.g., the NRU), and, therefore, significantly reduce chip area compared with using separate transformers for the first frequency band and the second frequency band.

In this example, the second switch 340 and the first switch 240 provide greater flexibility to inductance tuning compared with using only the first switch 240. The greater flexibility to inductance tuning provides greater flexibility in positioning the resonance frequency of the switchable transformer 210 at or close to a desired frequency within the first frequency band in the first mode and positioning the resonance frequency of the switchable transformer 210 at or close to a desired frequency within the second frequency band.

When the first switch 240 is turned on (i.e., closed) in the second mode, the first switch 240 closes a path between the first inductor 232 and the second inductor 234 that bypasses the third inductor 236. This path forms a closed loop with the third inductor 236 as shown in FIG. 3B. Similarly, when the second switch 340 is turned on (i.e., closed) in the second mode, the second switch 340 closes a path between the first inductor 332 and the second inductor 334 that bypasses the third inductor 336. This path forms a closed loop with the third inductor 336 as shown in FIG. 3B. During operation in the second mode, currents flow in the closed loops formed by closing the switches 240 and 340. The currents flowing in the closed loops cancel out a portion of the magnetic flux magnetically coupling the primary and secondary inductors 220 and 230. As a result, the primary and secondary Q factors of the switchable transformer 210 are degraded and energy loss between the primary and secondary inductors 220 and 230 is increased. The exemplary implementation shown in FIG. 2B also suffers from Q factor degradation caused by the closed loop formed by closing the first switch 240.

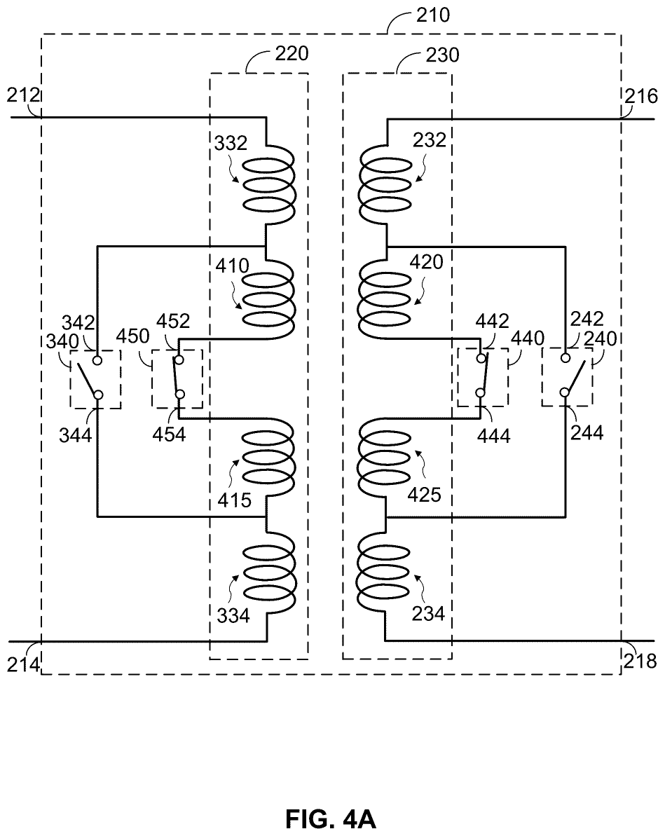

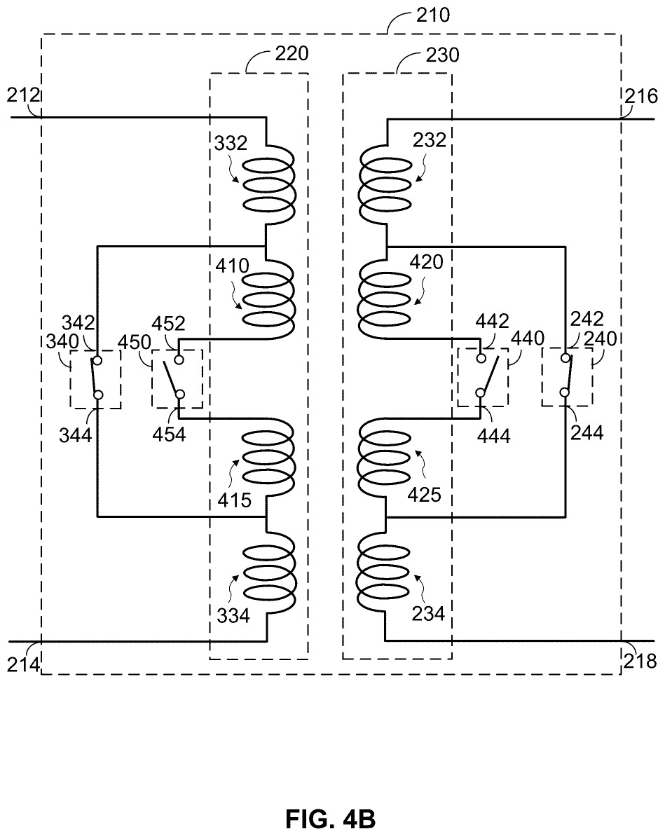

FIG. 4A shows an example in which the switchable transformer 210 further includes a third switch 440 and a fourth switch 450. As discussed further below, the third switch 440 and the fourth switch 450 are used to break the closed loops in the second mode discussed above to prevent Q factor degradation in the second mode.

In this example, the secondary inductor 230 includes the first inductor 232 and the second inductor 234 discussed above. The secondary inductor 230 also includes a third inductor 420 and a fourth inductor 425. The first terminal 242 of the first switch 240 is coupled between the first inductor 232 and the third inductor 420, and the second terminal 244 of the first switch 240 is coupled between the fourth inductor 425 and the second inductor 234. The third inductor 420 is coupled between the first terminal 242 of the first switch 240 and a first terminal 442 of the third switch 440. The fourth inductor 425 is coupled between a second terminal 444 of the third switch 440 and the second terminal 244 of the first switch 240.

In this example, the primary inductor 220 includes the first inductor 332 and the second inductor 334 discussed above. The primary inductor 220 also includes a third inductor 410 and a fourth inductor 415. The first terminal 342 of the second switch 340 is coupled between the first inductor 332 and the third inductor 410, and the second terminal 344 of the second switch 340 is coupled between the fourth inductor 415 and the second inductor 334. The third inductor 410 is coupled between the first terminal 342 of the second switch 340 and a first terminal 452 of the fourth switch 450. The fourth inductor 415 is coupled between a second terminal 454 of the fourth switch 450 and the second terminal 344 of the second switch 340.

In the first mode, the control circuit 250 (shown in FIGS. 2A, 2B, 3A, and 3B) turns off the first switch 240, turns off the second switch 340, turns on the third switch 440, and turns on the fourth switch 450. FIG. 4A shows the on/off states of the switches 240, 340, 440, and 450 in the first mode. In the first mode, the inductors 332, 410, 415, and 334 in the primary inductor 220 are coupled in series and contribute to the primary inductance. Also, the inductors 232, 420, 425, and 234 in the secondary inductor 230 are coupled in series and contribute to the secondary inductance. As discussed above, the primary and secondary inductances are higher in the first mode than the second mode, which results in a lower resonance frequency within the first frequency band (e.g., 5G band).

In the second mode, the control circuit 250 (shown in FIGS. 2A, 2B, 3A, and 3B) turns on the first switch 240, turns on the second switch 340, turns off the third switch 440, and turns off the fourth switch 450. FIG. 4B shows the on/off states of the switches 240, 340, 440, and 450 in the second mode. In the second mode, the first switch 240 bypasses the third inductor 420 and the fourth inductor 425, which reduces the secondary inductance. Also, the second switch 340 bypasses the third inductor 410 and the fourth inductor 415, which reduces the primary inductance. As discussed above, the lower primary and secondary inductances in the second mode result in a higher resonance frequency within the second frequency band (e.g., NRU band).

In the second mode, the third switch 440 between the third inductor 420 and the fourth inductor 425 in the secondary inductor 230 is turned off (i.e., opened) and the fourth switch 450 between the third inductor 410 and the fourth inductor 415 in the primary inductor 220 is turned off (i.e., opened). As a result, the closed loops shown in FIG. 3B are broken, which prevents currents from flowing in the closed loops and causing Q factor degradation.

As discussed above, the mixer 120 may output an RF signal in the first frequency band in the first mode and output an RF signal in the second frequency band in the second mode. In this regard, the frequency synthesizer 125 may be configured to set the frequency of the LO signal to a first frequency in the first mode and set the frequency of the LO signal to a second frequency in the second mode. In certain aspects, the second frequency is higher than the first frequency. In this example, the first frequency causes the mixer 120 to upconvert the baseband signal or the IF signal into the RF signal in the first frequency band and the second frequency causes the mixer 120 to upconvert the baseband signal or the IF signal into the RF signal in the second frequency band.

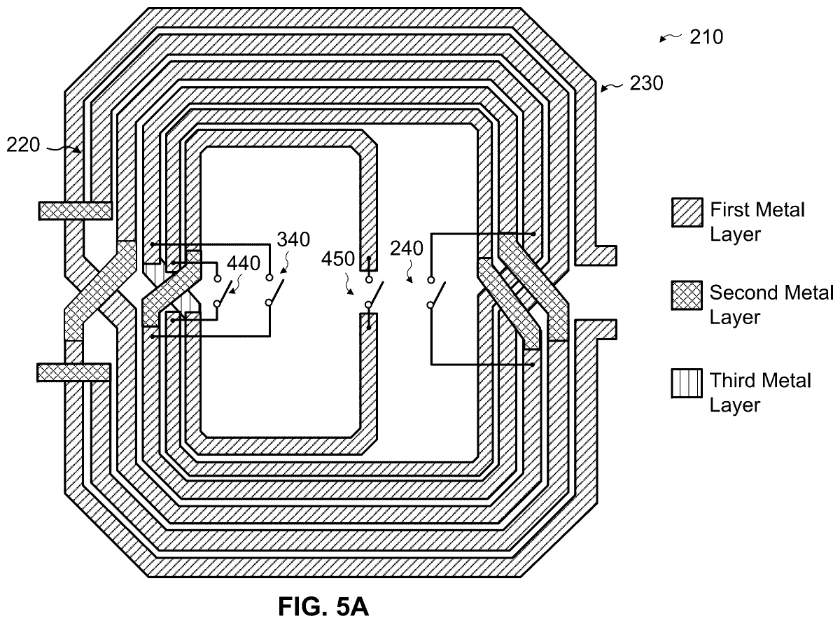

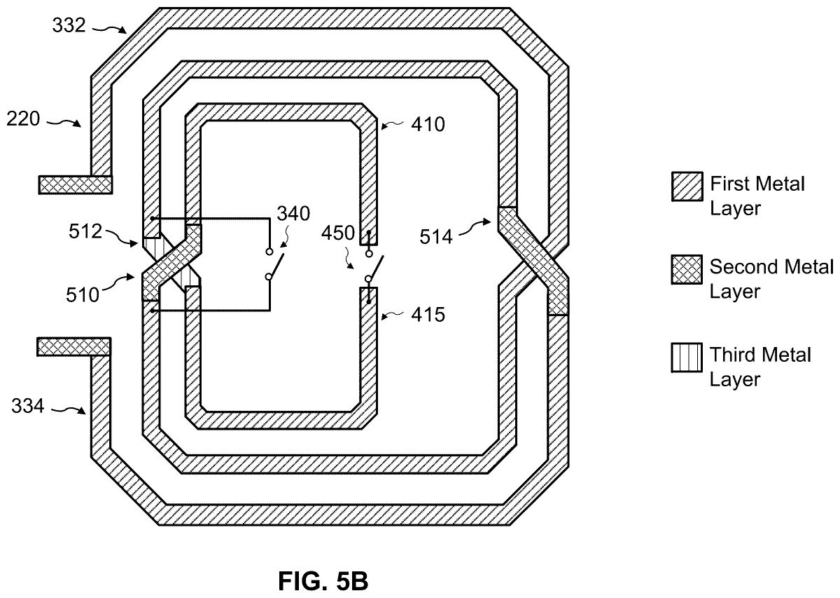

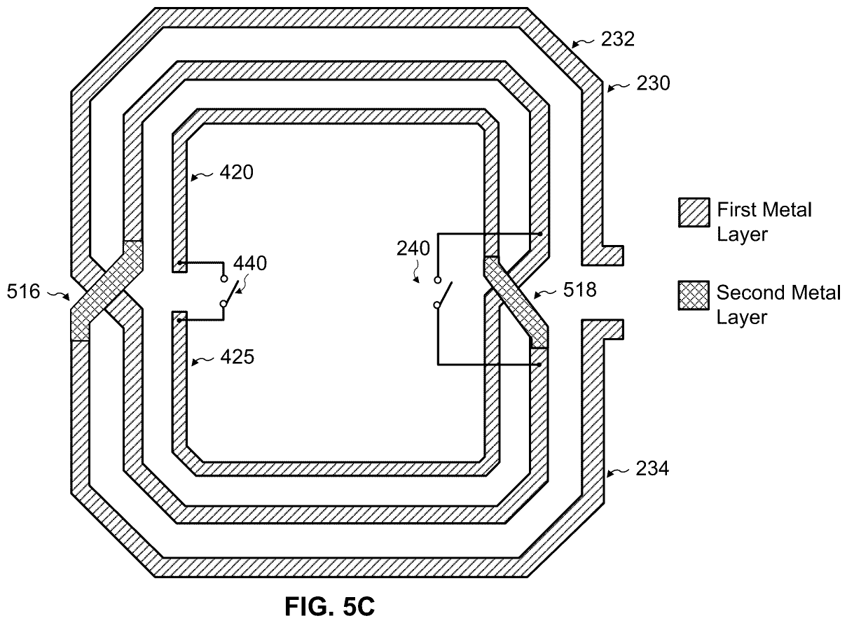

FIG. 5A shows a top view of an exemplary layout of the switchable transformer 210 according to certain aspects of the present disclosure. FIG. 5B shows the layout of FIG. 5A without the secondary inductor 230 to better show the primary inductor 220, and FIG. 5C shows the layout of FIG. 5A without the primary inductor 220 to better show the secondary inductor 230.

In this example, the primary inductor 220 and the secondary inductor 230 are formed (i.e., patterned) in a first metal layer on a chip (e.g., using lithographic and etching processes). Each of the inductors 220 and 230 may include a spiral inductor, a loop inductor, or another type of inductor. In this example, loops of the secondary inductor 230 are interleaved with loops of the primary inductor 220 to facilitate magnetic coupling between the primary inductor 220 and the secondary inductor 230.

The exemplary layout also include bridges 510, 514, 516, and 518 formed in a second metal layer and a bridge 512 formed in a third metal layer, as shown in FIGS. 5B and 5C. The second metal layer may be above the first metal layer and the third metal layer may be below the first metal layer, or vice versa. The bridges 510, 512, 514, 516, and 518 allow the primary inductor 220 and the secondary inductor 230 to cross one another without shorting.

Referring to FIG. 5B, each of the bridges 510 and 514 is coupled between respective portions of the primary inductor 220 by vias disposed between the first metal layer and the second metal layer. The bridge 512 is coupled between portions of the primary inductor 220 by vias disposed between the first metal layer and the third metal layer. As used herein, a “via” is a vertical interconnect structure that provides coupling between two different metal layers on a chip. FIG. 5B shows the locations at which the switches 340 and 450 are coupled to the primary inductor 220 in this example.

Referring to FIG. 5C, each of the bridges 516 and 518 is coupled between respective portions of the secondary inductor 230 by vias disposed between the first metal layer and the second metal layer. FIG. 5C shows the locations at which the switches 240 and 440 are coupled to the secondary inductor 230 in this example.

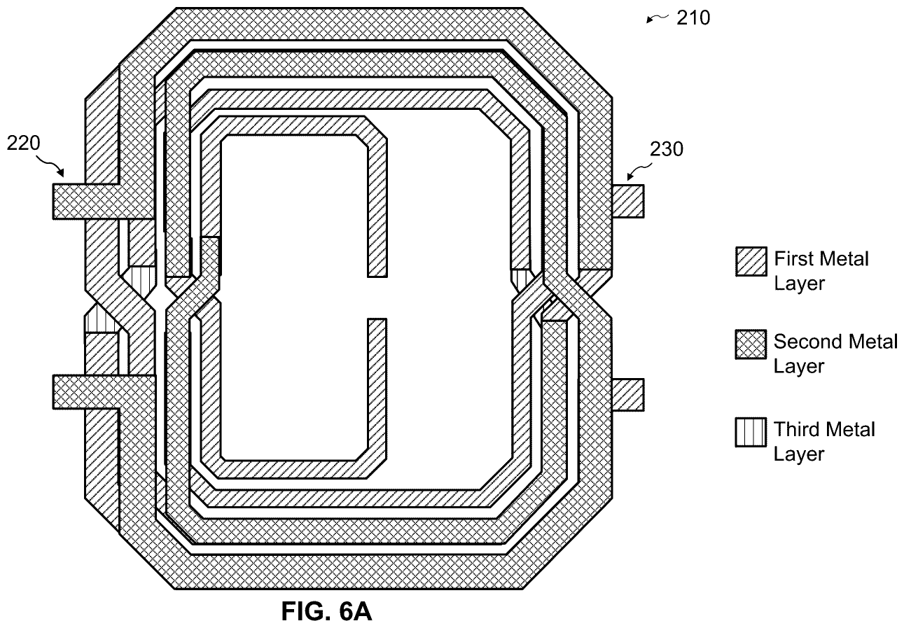

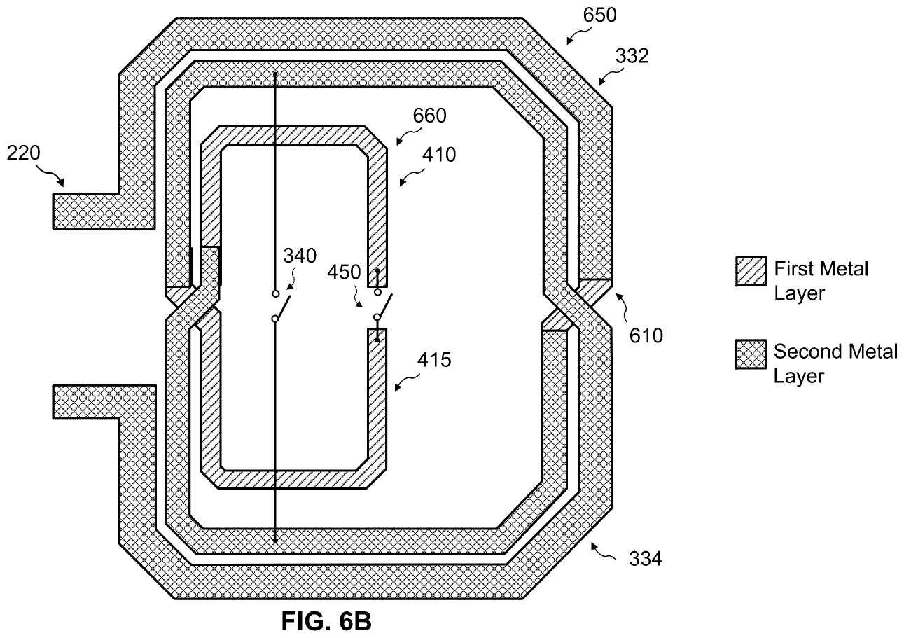

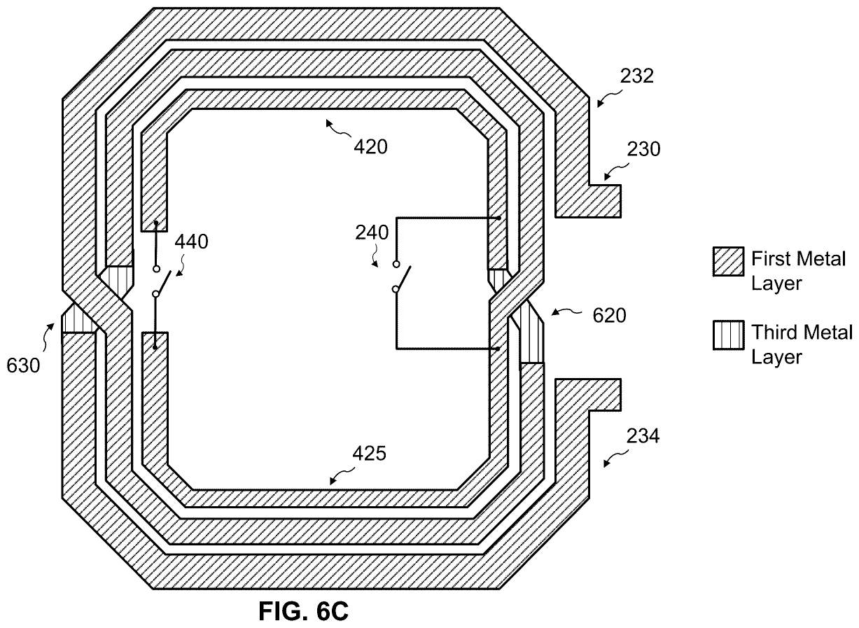

It is to be appreciated that the switchable transformer 210 is not limited to the exemplary layout shown in FIGS. 5A, 5B, and 5C. In this regard, FIG. 6A shows a top view of another exemplary layout of the switchable transformer 210 according to certain aspects of the present disclosure. FIG. 6B shows the layout of FIG. 6A without the secondary inductor 230 to better show the primary inductor 220, and FIG. 6C shows the layout of FIG. 6A without the primary inductor 220 to better show the secondary inductor 230.

In this example, the first inductor 332 and the second inductor 334 of the primary inductor 220 are vertically stacked with the secondary inductor 230. The vertical stacking improves magnetic coupling between the primary inductor 220 and the secondary inductor 230 and reduces chip area. In the example in FIG. 6A, the first inductor 332 and the second inductor 334 of the primary inductor 220 are stacked on top of the secondary inductor 230. For example, the secondary inductor 230 may be formed in the first metal layer and the first inductor 332 and the second inductor 334 of the primary inductor 220 may be formed in the second metal layer, in which the second metal layer is above the first metal layer. In this example, the third inductor 410 and the fourth inductor 415 of the primary inductor 220 may be formed in the first metal layer. In other implementations, portions of the third inductor 410 and the fourth inductor 415 of the primary inductor 220 may be formed in the first metal layer while other portions of the third inductor 410 and the fourth inductor 415 of the primary inductor 220 may be formed in the second metal layer.

Referring to FIG. 6B, the layout includes a bridge 610 formed in the first metal layer to couple portions of the primary inductor 220 formed in the second metal layer. In this example, the bridge 610 allows the primary inductor 220 to cross over itself without shorting. The portions of the primary inductor 220 formed in the first metal layer are coupled to the portions of the primary inductor 220 formed in the second metal layer by vias (not shown in FIG. 6B) disposed between the first metal layer and the second metal layer. In this example, the third inductor 410 and the fourth inductor 415 of the primary inductor 220 are formed in the first metal layer and are coupled to the first inductor 332 and the second inductor 334 of the primary inductor 220 formed in the second metal layer by vias (not shown). FIG. 6B shows the locations at which the switches 340 and 450 are coupled to the primary inductor 220 in this example.

Referring to FIG. 6C, the layout includes bridge 620 and 630 formed in the third metal layer to couple portions of the secondary inductor 230. In this example, the bridges 620 and 630 allow the secondary inductor 230 to cross over itself without shorting. FIG. 6C shows the locations at which the switches 240 and 440 are coupled to the secondary inductor 230 in this example.

Referring back to FIG. 6B, in this example, the primary inductor 220 includes two outer turns 650 formed in the second layer and an inner turn 660 formed in the first metal layer. As shown in FIG. 6A, the two outer turns 650 are disposed above the secondary inductor 230 and overlap the secondary inductor 230. In the example in FIG. 6B, the two outer turns 650 provide the first inductor 332 and the second inductor 334 of the primary inductor 220, and the inner turn provides the third inductor 410 and the fourth inductor 415 of the primary inductor 220. It is to be appreciated that the primary inductor 220 is not limited to the example of two outer turns formed in the second metal layer and one inner turn formed in the first metal layer. In general, the primary inductor 220 may include one or more outer turns formed in the second metal layer and one or more inner turns formed in the first metal layer.

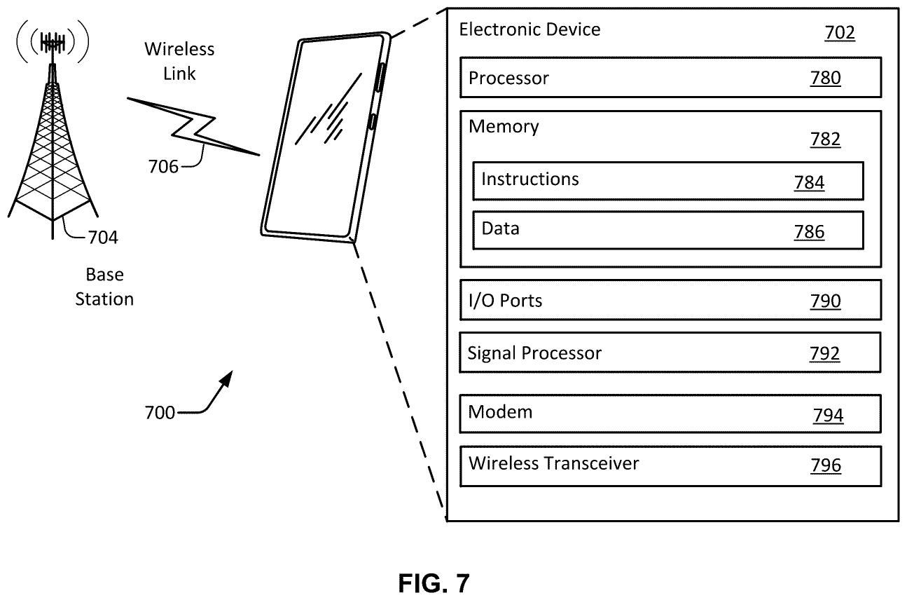

FIG. 7 is a diagram of an environment 700 that includes a wireless device 702 and a base station 704. In the environment 700, the wireless device 702 communicates with the base station 704 via a wireless link 706. As shown, the wireless device 702 is depicted as a smart phone. However, it is to be understood that the wireless device 702 may be implemented as any suitable wireless device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 704 communicates with the wireless device 702 via the wireless link 706, which may be implemented as any suitable type of wireless link. Although depicted as a base station tower of a cellular radio network, the base station 704 may represent or be implemented as another device, such as a satellite, a terrestrial broadcast tower, an access point, a peer-to-peer device, a mesh network node, and so forth. The wireless link 706 may include a downlink of data and/or control information communicated from the base station 704 to the wireless device 702 and an uplink of other data and/or control information communicated from the wireless device 702 to the base station 704. The wireless link 706 may be implemented using any suitable communication protocol or standard, such as 3rd Generation Partnership Project Long-Term Evolution (3GPP LTE, 3GPP NR 5G), IEEE 702.77, IEEE 702.77, Bluetooth™, and so forth.

The wireless device 702 includes a processor 780 and a memory 782. The memory 782 may be or form a portion of a computer readable storage medium. The processor 780 may include any type of processor, such as an application processor or a multi-core processor, that is configured to execute processor-executable instructions stored in the memory 782. The memory 782 may include any suitable type of data storage media, such as a volatile memory (e.g., random access memory (RAM)), a non-volatile memory (e.g., Flash memory), an optical media, a magnetic media (e.g., disk or tape), or any combination thereof. In the context of this disclosure, the memory 782 may store instructions 784, data 786, and other information of the wireless device 702.

The wireless device 702 may also include input/output (I/O) ports 790. The I/O ports 790 enable data exchanges or interaction with other devices, networks, or users or between components of the wireless device 702.

The wireless device 702 may further include a signal processor (SP) 792 (e.g., such as a digital signal processor (DSP)). The signal processor 792 may function similar to the processor 780 and may be capable of executing instructions and/or processing information in conjunction with the memory 782.

For communication purposes, the wireless device 702 also includes a modem 794, a wireless transceiver 796, and one or more antennas (e.g., the antenna 170). The wireless transceiver 796 may include the mixer 120, the switchable transformer 210, the driver amplifier 150, and/or the power amplifier 160 discussed above. The wireless transceiver 796 provides connectivity to respective networks (e.g., the base station 704) and other wireless devices connected therewith using RF signals. The wireless transceiver 796 may facilitate communication over any suitable type of wireless network, such as a wireless local area network (LAN) (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

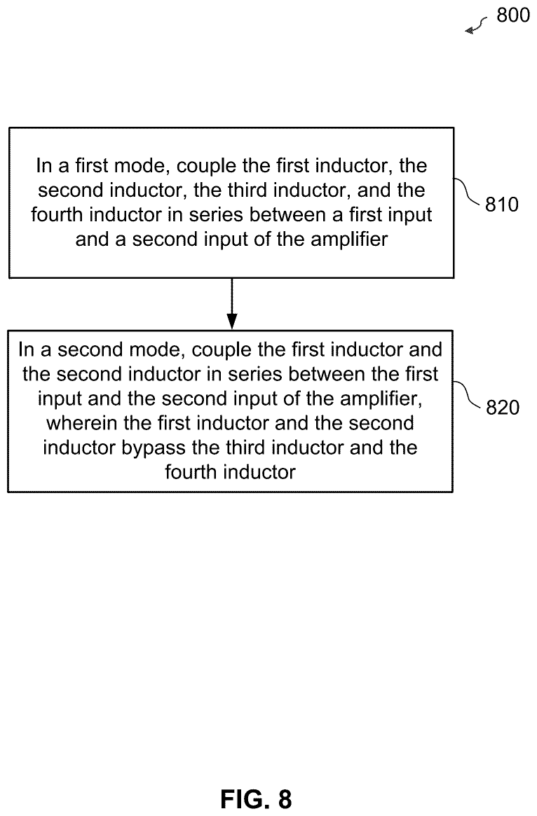

FIG. 8 illustrates a method 800 operating in a wireless device. The wireless device (e.g., the wireless device 130) includes a switchable transformer (e.g., switchable transformer 210) coupled between a mixer (e.g., the mixer 120) and an amplifier (e.g., the driver amplifier 150), the switchable transformer including a primary inductor (e.g., the primary inductor 220) and a secondary inductor (e.g., the secondary inductor 230) magnetically coupled with the primary inductor, the secondary inducting including a first inductor (e.g., the first inductor 232), a second inductor (e.g., the second inductor 234), a third inductor (e.g., the third inductor 420), and a fourth inductor (e.g., the fourth inductor 425).

At block 810, in a first mode, the first inductor, the second inductor, the third inductor, and the fourth inductor are coupled in series between a first input and a second input of the amplifier. For example, the first inductor, the second inductor, the third inductor, and the fourth inductor may be coupled in series by the third switch 440.

At block 820, in a second mode, the first inductor and the second inductor are coupled in series between the first input and the second input of the amplifier, wherein the first inductor and the second inductor bypass the third inductor and the fourth inductor. For example, the first inductor and the second inductor may be coupled in series between the first input and the second input of the amplifier by the first switch 240.

In certain aspects, the method 800 further includes, in the first mode, closing a switch between the third inductor and the fourth inductor, and, in the second mode, opening the switch between the third inductor and the fourth inductor. For example, the switch may correspond to the third switch 440, and the third switch 440 may be opened and closed by the control circuit 250.

In certain aspects, the method 800 further includes outputting a local oscillator (LO) signal to the mixer, setting the LO signal to a first frequency in the first mode, and setting the LO signal to a second frequency in the second mode. For example, the LO signal may be output by the frequency synthesizer 125. In certain aspects, the second frequency is higher than the first frequency.

Implementation examples are described in the following numbered clauses:

1. A system, comprising:
a mixer;
an amplifier; and
a switchable transformer, comprising:
   a primary inductor coupled between a first output and a second output of the mixer;
   a first switch;
   a second switch; and
   a secondary inductor coupled between a first input and a second input of the amplifier, wherein the secondary inductor is magnetically coupled with the primary inductor, and the secondary inductor comprises:
      a first inductor coupled between the first input of the amplifier and a first terminal of the first switch;
      a second inductor coupled between a second terminal of the first switch and the second input of the amplifier;
      a third inductor coupled between the first terminal of the first switch and a first terminal of the second switch; and
      a fourth inductor coupled between the second terminal of the first switch and a second terminal of the second switch.

2. The system of clause 1, further comprising a control circuit configured to:
in a first mode, turn on the second switch and turn off the first switch; and
in a second mode, turn off the second switch and turn on the first switch.

3. The system of clause 2, wherein:
in the first mode, the mixer is configured to output a first RF signal within a first frequency band; and
in the second mode, the mixer is configured to output a second RF signal within a second frequency band that is higher than the first frequency band.

4. The system of clause 2 or 3, further comprising a frequency synthesizer coupled to the mixer, wherein the frequency synthesizer is configured to:
output a local oscillator (LO) signal to the mixer;
set the LO signal to a first frequency in the first mode; and
set the LO signal to a second frequency in the second mode.

5. The system of clause 4, wherein the second frequency is higher than the first frequency.

6. The system of any one of clauses 1 to 5, wherein the switchable transformer further comprises a third switch and a fourth switch, and the primary inductor further comprises:
a fifth inductor coupled between the first output of the mixer and a first terminal of the third switch;
a sixth inductor coupled between a second terminal of the third switch and the second output of the mixer;
a seventh inductor coupled between the first terminal of the third switch and a first terminal of the fourth switch; and
an eighth inductor coupled between the second terminal of the third switch and a second terminal of the fourth switch.

7. The system of clause 6, further comprising a control circuit configured to:
in a first mode, turn on the second switch, turn on the fourth switch, turn off the first switch, and turn off the third switch; and
in a second mode, turn off the second switch, turn off the fourth switch, turn on the first switch, and turn on the third switch.

8. The system of clause 7, wherein:
in the first mode, the mixer is configured to output a first RF signal within a first frequency band; and
in the second mode, the mixer is configured to output a second RF signal within a second frequency band that is higher than the first frequency band.

9. The system of clause 7 or 8, further comprising a frequency synthesizer coupled to the mixer, wherein the frequency synthesizer is configured to:
output a local oscillator (LO) signal to the mixer;
set the LO signal to a first frequency in the first mode; and
set the LO signal to a second frequency in the second mode.

10. The system of clause 9, wherein the second frequency is higher than the first frequency.

11. The system of any one of clauses 6 to 10, wherein the fifth inductor and the sixth inductor are stacked vertically with the secondary inductor.

12. The system of clause 11, wherein the seventh inductor, the eighth inductor, and the secondary inductor are formed in a first metal layer, and the fifth inductor and the sixth inductor are formed in a second metal layer.

13. The system of clause 12, wherein the second metal layer is above the first metal layer.

14. The system of any one of clauses 1 to 13, wherein the primary inductor includes one or more outer turns and one or more inner turns, the one or more inner turns and the secondary inductor are formed in a first metal layer, and the one or more outer turns are formed in a second metal layer.

15. The system of clause 14, wherein the second metal layer is above the first metal layer.

16. The system of clause 15, wherein the one or more outer turns overlap the secondary inductor.

17. A system, comprising:
a mixer;
a driver amplifier;
a power amplifier coupled to an output of the driver amplifier;
a switchable transformer, comprising:
   a primary inductor coupled between a first output and a second output of the mixer;
   a first switch;
   a second switch; and
   a secondary inductor coupled between a first input and a second input of the driver amplifier, wherein the secondary inductor is magnetically coupled with the primary inductor, and the secondary inductor comprises:
      a first inductor coupled between the first input of the driver amplifier and a first terminal of the first switch;
      a second inductor coupled between a second terminal of the first switch and the second input of the driver amplifier;
      a third inductor coupled between the first terminal of the first switch and a first terminal of the second switch; and
      a fourth inductor coupled between the second terminal of the first switch and a second terminal of the second switch.

18. The system of clause 17, further including an antenna coupled to an output of the power amplifier.

19. A method for operating a wireless device, the wireless device including a switchable transformer coupled between a mixer and an amplifier, the switchable transformer including a primary inductor and a secondary inductor magnetically coupled with the primary inductor, the secondary inducting including a first inductor, a second inductor, a third inductor, and a fourth inductor, the method comprising:
in a first mode, coupling the first inductor, the second inductor, the third inductor, and the fourth inductor in series between a first input and a second input of the amplifier; and
in a second mode, coupling the first inductor and the second inductor in series between the first input and the second input of the amplifier, wherein the first inductor and the second inductor bypass the third inductor and the fourth inductor.

20. The method of clause 19, further comprising:
in the first mode, closing a switch between the third inductor and the fourth inductor; and
in the second mode, opening the switch between the third inductor and the fourth inductor.

21. The method of clause 19 or 20, further comprising:
outputting a local oscillator (LO) signal to the mixer;
setting the LO signal to a first frequency in the first mode; and
setting the LO signal to a second frequency in the second mode.

22. The method of clause 21, wherein the second frequency is higher than the first frequency.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. It is also to be appreciated that an “inductor” may include multiple inductors coupled in series. It is also to be appreciated than an “input” may be a single-ended input, a differential input, or one of two inputs of a differential input, and an “output” may be a single-ended output, a differential output, or one of two outputs of a differential output. The term “approximately” means within a range of between 90 percent and 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. Also, the disclosure is not limited to the exemplary number designations used above. For example, the first switch 240 and the third switch 440 may also be referred to as the first switch and the second switch, respectively, and the second switch 340 and the fourth switch 450 may also be referred to as the third switch and the fourth switch, respectively. In another example, the inductors 332, 334, 410, and 415 may also be referred to as the fifth, sixth, seventh, and eighth inductors, respectively.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system, comprising:
a mixer;
an amplifier; and
a switchable transformer, comprising:
a primary inductor coupled between a first output and a second output of the mixer;
a first switch;
a second switch; and
a secondary inductor coupled between a first input and a second input of the amplifier, wherein the secondary inductor is magnetically coupled with the primary inductor, and the secondary inductor comprises:
a first inductor coupled between the first input of the amplifier and a first terminal of the first switch;
a second inductor coupled between a second terminal of the first switch and the second input of the amplifier;
a third inductor coupled between the first terminal of the first switch and a first terminal of the second switch; and
a fourth inductor coupled between the second terminal of the first switch and a second terminal of the second switch.

2. The system of claim 1, further comprising a control circuit configured to:
in a first mode, turn on the second switch and turn off the first switch; and
in a second mode, turn off the second switch and turn on the first switch.

3. The system of claim 2, wherein:
in the first mode, the mixer is configured to output a first RF signal within a first frequency band; and
in the second mode, the mixer is configured to output a second RF signal within a second frequency band that is higher than the first frequency band.

4. The system of claim 2, further comprising a frequency synthesizer coupled to the mixer, wherein the frequency synthesizer is configured to:
output a local oscillator (LO) signal to the mixer;
set the LO signal to a first frequency in the first mode; and
set the LO signal to a second frequency in the second mode.

5. The system of claim 4, wherein the second frequency is higher than the first frequency.

6. The system of claim 1, wherein the switchable transformer further comprises a third switch and a fourth switch, and the primary inductor further comprises:
a fifth inductor coupled between the first output of the mixer and a first terminal of the third switch;
a sixth inductor coupled between a second terminal of the third switch and the second output of the mixer;
a seventh inductor coupled between the first terminal of the third switch and a first terminal of the fourth switch; and
an eighth inductor coupled between the second terminal of the third switch and a second terminal of the fourth switch.

7. The system of claim 6, further comprising a control circuit configured to:
in a first mode, turn on the second switch, turn on the fourth switch, turn off the first switch, and turn off the third switch; and
in a second mode, turn off the second switch, turn off the fourth switch, turn on the first switch, and turn on the third switch.

8. The system of claim 7, wherein:
in the first mode, the mixer is configured to output a first RF signal within a first frequency band; and
in the second mode, the mixer is configured to output a second RF signal within a second frequency band that is higher than the first frequency band.

9. The system of claim 7, further comprising a frequency synthesizer coupled to the mixer, wherein the frequency synthesizer is configured to:
output a local oscillator (LO) signal to the mixer;
set the LO signal to a first frequency in the first mode; and
set the LO signal to a second frequency in the second mode.

10. The system of claim 9, wherein the second frequency is higher than the first frequency.

11. The system of claim 6, wherein the fifth inductor and the sixth inductor are stacked vertically with the secondary inductor.

12. The system of claim 11, wherein the seventh inductor, the eighth inductor, and the secondary inductor are formed in a first metal layer, and the fifth inductor and the sixth inductor are formed in a second metal layer.

13. The system of claim 12, wherein the second metal layer is above the first metal layer.

14. The system of claim 1, wherein the primary inductor includes one or more outer turns and one or more inner turns, the one or more inner turns and the secondary inductor are formed in a first metal layer, and the one or more outer turns are formed in a second metal layer.

15. The system of claim 14, wherein the second metal layer is above the first metal layer.

16. The system of claim 15, wherein the one or more outer turns overlap the secondary inductor.

17. A system, comprising:
a mixer;
a driver amplifier;
a power amplifier coupled to an output of the driver amplifier;
a switchable transformer, comprising:
a primary inductor coupled between a first output and a second output of the mixer;
a first switch;
a second switch; and
a secondary inductor coupled between a first input and a second input of the driver amplifier, wherein the secondary inductor is magnetically coupled with the primary inductor, and the secondary inductor comprises:
a first inductor coupled between the first input of the driver amplifier and a first terminal of the first switch;
a second inductor coupled between a second terminal of the first switch and the second input of the driver amplifier;
a third inductor coupled between the first terminal of the first switch and a first terminal of the second switch; and
a fourth inductor coupled between the second terminal of the first switch and a second terminal of the second switch.

18. The system of claim 17, further including an antenna coupled to an output of the power amplifier.

19. A method for operating a wireless device, the wireless device including a switchable transformer coupled between a mixer and an amplifier, the switchable transformer including a primary inductor and a secondary inductor magnetically coupled with the primary inductor, the secondary inducting including a first inductor, a second inductor, a third inductor, and a fourth inductor, the method comprising:
in a first mode, coupling the first inductor, the second inductor, the third inductor, and the fourth inductor in series between a first input and a second input of the amplifier; and
in a second mode, coupling the first inductor and the second inductor in series between the first input and the second input of the amplifier, wherein the first inductor and the second inductor bypass the third inductor and the fourth inductor.

20. The method of claim 19, further comprising:
in the first mode, closing a switch between the third inductor and the fourth inductor; and
in the second mode, opening the switch between the third inductor and the fourth inductor.
